(19) United States
(12) Patent Application Publication
(10) Pub. No.: US 2013/0169310 A1
(43) Pub. Date: Jul. 4, 2013

(54) TESTING CIRCUIT FOR DC-DC CONVERTER

(71) Applicant: SILICON WORKS CO., LTD., Daejeon-si (KR)

(72) Inventors: Young Jin WOO, Daejeon-si (KR); In Sun JEON, Daejeon-si (KR); Bo Min KWON, Busan-si (KR)

(73) Assignee: SILICON WORKS CO., LTD., Daejeon-si (KR)

(21) Appl. No.: 13/729,335

(22) Filed: Dec. 28, 2012

(30) Foreign Application Priority Data
Dec. 30, 2011 (KR) 10-2011-0146977

(51) Int. Cl. G01R 31/40

(52) U.S. Cl. CPC G01R 31/40
USPC 324/764.01

(57) ABSTRACT

Provided is a testing circuit capable of testing functionality of various DC-DC converters without an inductor. According to the present invention, various electronic elements forming the testing circuit for a DC-DC converter are converted in the same kinds of elements or different elements in one-to-one or one-to-two or more correspondence to electronic elements forming a typical DC-DC converter. When the conversion is performed, the electronic values of the elements may be properly scaled to test the DC-DC converter without consuming high power. Therefore, various problems of the related art are minimized.

### BACKGROUND OF THE INVENTION

1. Field of the Invention

The present invention relates to a testing circuit for a DC-DC converter, and more particularly, to a testing circuit capable of performing an operation test without an inductor causing high power consumption when a DC-DC converter is intended to be tested.

2. Description of the Related Art

With the development of semiconductor fabrication technology for several tens of years, the number of semiconductor chips embedded in one electronic device has rapidly increased. The development of semiconductor technology has also promoted the development of communication technology and system technology. Recently, portable electronic devices have made much progress. In the portable electronic device, personal entertainment tasks as well as official engagements have increased explosively. The personal entertainment tasks may include playing an audio file such as MP3 file, taking and reproducing moving pictures or still pictures, and operating various messenger programs. Therefore, the load of the mobile electronic device is determined by the entertainment programs. Such a tendency is gradually increasing.

In order to satisfy various services required by portable electronic devices such as mobile phone, notebook computer, and PDA, a stronger computing ability must be provided. This means that to efficiently control and manage main power supplied from a battery became an important issue. A circuit configuration or integrated circuit to control and manage main power is referred to as a power management integrated circuit (PMIC).

The PMIC includes individual circuits for power, high-voltage circuits, digital circuits using a low voltage, analog circuits, control circuits the like which are formed in one chip or divided into two chips. Unlike dynamic random access memory (DRAM), strict standards are not applied to the PMIC. Therefore, various circuits may be properly added or removed depending on the use environment. The PMIC actively responds to efficiently supply power to loads which consume various power supply voltages and various currents. Therefore, the PMIC generally includes a DC-DC converter, a voltage regulator, a controller and the like. Among them, the DC-DC converter is necessarily included in the PMIC. For example, MAX17065, Maxim electronic component, is a PMIC which is manufactured so as to be suitable for an organic light emitting diode (OLED) display. The PMIC includes a DC-DC converter, an inverting DC-DC converter, two kinds of regulators, a low drop out (LDO) circuit and the like, and has an external interface suitable for I²C.

When supposing that a battery of the portable electronic device has a power supply ability of 3.7V/1500 mA and various circuits using the electromotive force require four kinds of power supply voltages, the DC-DC converter must supply the four kinds of power supply voltages. Therefore, four output voltages or four DC-DC converters are needed. Korean Patent Laid-open Publication No. 10-2010-009882 (Sep. 10, 2010) discloses an example in which a DC-DC converter having various outputs is applied to a PMIC. Furthermore, Korean Patent Laid-open Publication No. 10-2009-000931 (Jan. 22, 2009) discloses an example in which a PMIC is applied to various mobile electronic devices.

In general, the DC-DC converter must transmit a high power of several hundred mA to several A. Therefore, the DC-DC converter may have an inductor-based circuit structure. In particular, a non-isolated inductive DC-DC converter is usually used in the portable electronic device. The non-isolated inductive DC-DC converter refers to a DC-DC converter in which an input terminal and an internal terminal are not isolated from each other and an inductor is used as an energy storage and transmission element. On the other hand, an isolated inductive DC-DC converter refers to a DC-DC converter in which an input-side circuit and an output-side circuit are physically isolated from each other and an input-side inductor and an output-side inductor are adjacent to each other to transmit power according to an electromagnetic induction method.

The non-isolated inductive DC-DC converter is classified into various converters depending on operation methods. For example, the non-isolated inductive DC-DC converter may be classified depending on the relative magnitude between input and output voltages. More specifically, the non-isolated inductive DC-DC converter is classified into a boost DC-DC converter when the output voltage is larger than the input voltage, a buck DC-DC converter when the output voltage is smaller than the input voltage, and a buck-boost DC-DC converter when the output voltage may be larger or smaller than the input voltage depending on the operation state of the circuit.

FIG. 1 illustrates a boot DC-DC converter among typical non-isolated inductive DC-DC converters. FIG. 1 is a diagram for explaining a basic operation of the boost DC-DC converter, and an actual circuit may have a more complex configuration. Referring to FIG. 1, an inductor 110 is connected between an input voltage VIN and a switch 120, which indicates that the circuit has non-isolated and inductive properties. During a test, the input voltage VIN is supplied from a testing device. Since a voltage applied across a diode 130 is changed by the inductor 110 and the switch 120, the diode 130 repeats a switching operation between ‘on’ state and ‘off’ state. According to the switching operation, an average output voltage VO is generated from both ends of an output capacitor 140 and an output current IO is uniformly supplied, during a steady state operation. The output current IO refers to a current supplied to a load.

A parasitic resistance 170 is added at the lower end of the capacitor. A sensing resistor 160 is a resistor to sense a current value ISW flowing into a switching transistor 120, and must not have an effect on the operation characteristic of the switching transistor 120. Therefore, the sensing resistor 160 may have a small value, and may be omitted depending on cases. The current value flowing through the sensing resistor 160 is easily converted when the Ohm's law is used after a voltage applied across the sensing resistor 160 is measured. A gate signal VG of the switching transistor 120 is a signal for controlling a switching operation. The switching transistor 120 may be embedded in the PMIC or separately provided outside the PMIC. This configuration may be determined by the circuit's designer, depending on whether a power capacity is large or small. Furthermore, the switching transistor 120 may include the same kind of transistors as MOSFET, BJT, and IGBT which are generally well-known. The resistance 170 indicates an equivalent series resistance (ESR) of the capacitor 140. When the capacitor 140 is used as a multi-layer ceramic capacitor (MLCC), the resistance 210 may have a value ranging from several mΩ to several tens mΩ.

When the PMIC is used in a cellular phone, for example, the DC-DC converter within the PMIC must have a driving ability enough to drive other elements outside the PMIC, such as display controller, wireless controller, memory device, and various codec circuits. The driving ability indicates the magnitude the output current IO of the DC-DC converter, and has a range of several hundreds mA. When the PMIC has such a driving ability, the size of the inductor inevitably increases. Thus, it is impossible to embed the inductor into one chip due to the size of the inductor. For this reason, the inductor of the DC-DC converter is provided outside the PMIC chip.

However, before the DC-DC converter is mass-produced, a test must be previously performed to determine whether or not the DC-DC converter satisfies desired characteristics. At this time, many problems occur. First, noise may occur due to a switching operation of a switching element. Furthermore, noise of the switching element increases in proportion to the noise caused by the switching operation, due to the characteristics of the DC-DC converter which must pass a large current. Second, an error may occur when a current to be applied to the DC-DC converter from a testing device is so large as to increase the burden of the testing device. For example, suppose that three DC-DC converters are connected to the testing device and each of the DC-DC converters must pass an output current of 1 A. In this case, when a ratio of input voltage to output voltage is set to 4 (Vout/Vin=4) and conversion efficiency is set to 0.8, a current to be outputted from the testing device becomes 15 A. At this time, since parasitic components existing in various elements such as an inductor of the testing device or the DC-DC converter have a large effect on the test result, the precision of the test decreases. Accordingly, the yield of an IC to be tested also rapidly decreases. Although the parasitic resistance inside the inductor is only 0.1Ω, a voltage error of 1.5V is caused by the current of 15 A. The above-described problems commonly occur in all of the boost DC-DC converter, the buck DC-DC converter, and the boost-buck DC-DC converter.

### SUMMARY OF THE INVENTION

Accordingly, the present invention has been made in an effort to solve the problems occurring in the related art, and an object of the present invention is to provide a test circuit capable of testing functionality of a DC-DC converter through only a small current without using an inductor.

In order to achieve the above object, according to one aspect of the present invention, there is provided a testing circuit for a DC-DC converter including: an input current source; a first energy storage element having one terminal electrically connected to the input current source and the other terminal connected to a ground voltage; a plurality of first switches and second switches controlled by a switching control signal; a voltage source interconnected to a current value flowing in an output terminal; a first dependent current source having one terminal connected to the output terminal and controlled by a diode voltage; a second dependent current source having one terminal connected to the output terminal and the one terminal of the first dependent current source and controlled by a voltage of the voltage source; an output current source having one terminal connected to one or more of the first switches and the other terminal connected to the ground voltage; and a second energy storage element connected to the output terminal.

According to another aspect of the present invention, there is provided a testing circuit for a DC-DC converter which has an input terminal to receive an input current source and an output terminal to output an output voltage. The testing circuit includes: a plurality of first switches electrically connected to the input terminal and controlled by a switching control signal; a plurality of second switches electrically connected to the input terminal, controlled by the switching control signal, and operating in the opposite phase of the first switches; a first capacitor electrically connected to the input terminal; an output current source electrically connected to the input terminal; a second capacitor electrically connected to the output terminal; a first dependent current source having one terminal electrically connected to the output terminal; a second dependent current source electrically having one terminal electrically connected to the output terminal; and a voltage source interconnected to a current value flowing in the output terminal.

According to another aspect of the present invention, there is provided a testing circuit for a DC-DC converter including: a first current source having one terminal connected to a first power supply voltage, dependent on an input voltage, and controlled by a first switching signal; a first capacitor connected between the other terminal of the first current source and a ground voltage; a second current source having one terminal connected to a second power supply voltage, dependent on the voltage of the other terminal of the first current source, and controlled by a second switching signal; a fourth current source connected between the other terminal of the first current source and a fourth power supply voltage, dependent on an output voltage, and controlled by a fourth switching signal; and a third current source connected between the other terminal of the second current source and a third power supply voltage, dependent on a voltage converted from an output load current, and controlled by a third switching signal.

### BRIEF DESCRIPTION OF THE DRAWINGS

The above objects, and other features and advantages of the present invention will become more apparent after a reading of the following detailed description taken in conjunction with the drawings, in which:

FIG. 1 is a simple circuit diagram of a typical boost DC-DC converter;

FIG. 2 illustrates a converted testing circuit for a boost DC-DC converter according to an embodiment of the present invention;

FIG. 3 is a timing diagram for the circuits of FIGS. 1 and 2;

FIG. 4 illustrates a testing circuit for a boost DC-DC converter according to the embodiment of the present invention;

FIG. 5 is a simple circuit diagram of a typical boost DC-DC converter;

FIG. 6 illustrates a converted testing circuit for a buck DC-DC converter according to another embodiment of the present invention;

FIG. 7 is a timing diagram for the circuits of FIGS. 5 and 6;

FIG. 8 illustrates a testing circuit for a buck DC-DC converter according to the embodiment of the present invention;

FIG. 9 is a simple circuit diagram of a typical boost-buck DC-DC converter;

FIG. 10 illustrates a converted testing circuit for a boost-buck DC-DC converter according to another embodiment of the present invention;

FIG. 11 is a timing diagram for the circuits of FIGS. 9 and 10;

FIG. 12 illustrates a testing circuit for a boost-buck DC-DC converter according to the embodiment of the present invention; and

FIG. 13 illustrates a testing circuit for a DC-DC converter according to the embodiment of the present invention.

### DETAILED DESCRIPTION OF PREFERRED EMBODIMENTS

Throughout the present specification, terms such as ‘electrically connected’ and ‘connected’ between individual components may include direct connection and connection through an intermediate medium while the property of the connection is maintained at a predetermined level or more. Furthermore, terms such as ‘transmitted’ and ‘derived’ may include direct transmission and indirect transmission through an intermediate medium while the property of a signal is maintained at a predetermined level or more. In addition, terms such as ‘applied’ must be analyzed in the same manner throughout the present specification.

Reference will now be made in greater detail to a preferred embodiment of the invention, an example of which is illustrated in the accompanying drawings. Wherever possible, the same reference numerals will be used throughout the drawings and the description to refer to the same or like parts.

In the embodiments of the present invention, an inductor or output capacitor having a large capacity is excluded and substituted with another element so as to test functionality of a PMIC or DC-DC converter. However, the embodiments of the present invention are not directed to a technology for transmitting high power when a PMIC drives an actual element.

Hereinafter, circuit elements of a conventional DC-DC converter are substituted with other elements while the values thereof are scaled down. The operation of the DC-DC converter may be simulated by the substitute elements.

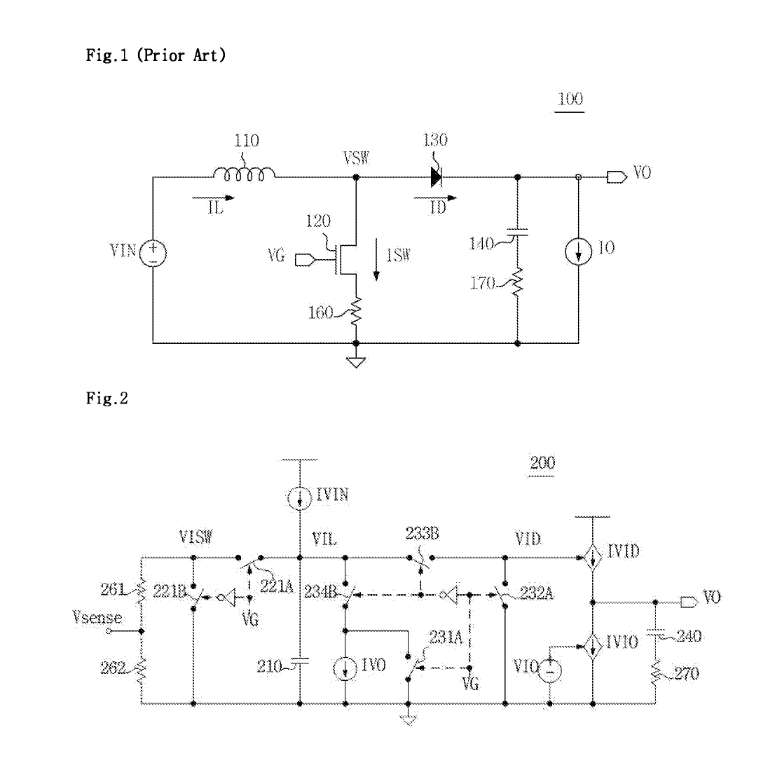

FIG. 2 illustrates a testing circuit for a boost DC-DC converter according to an embodiment of the present invention. In FIG. 2, components of the testing circuit correspond one-to-one or one-to-two to the components of the conventional boost DC-DC converter illustrated in FIG. 1. Depending on cases, the components may correspond one-to-three or more to the components of the conventional boost DC-DC converter. This configuration may be applied to other embodiments of the present invention. When the configuration of FIG. 2 is described, ‘present invention’ indicates the embodiment illustrated in FIG. 2, and ‘related art’ indicates the conventional circuit illustrated in FIG. 1. However, ‘related art’ does not indicate all related arts published or proposed in the art.

An input current source IVIN according to the present invention corresponds to the input voltage VIN according to the related art. Since the input current source IVIN is influenced by the input voltage VIN, the input current source IVIN may become an input dependent current source. When the input voltage VIN is 24V, 24V is divided by 10KΩ and scaled down ten thousand times to 2.4 mA in the present invention. Since the voltage is converted into the current, the voltage is scaled down while the physical unit thereof is changed, but the voltage value thereof is not changed. Hereinafter, the scaling is performed in the same manner.

In this way, an output voltage VO of 60V is converted into an output current source IVO of 6.0 mA, and the existence of an output terminal VO is maintained. Since the output current source IVO is influenced by the output voltage VO, the output current source IVO may become an output dependent current source.

When a switch voltage VSW is {0, VO}, the switch voltage VSW is simply converted into a logic swing {high, low}, a switching control signal VG is converted while the logic swing {low, high} thereof is maintained, and the inductor 110 of FIG. 1 is converted into a capacitor 210 of FIG. 2. Furthermore, the sensing resistor 160 of FIG. 1 is converted into two resistors 261 and 262 of FIG. 2, and an inductor current IL of 1 A is converted into a node voltage VIL of 1V. Since the sensing resistor 160 may be omitted depending on cases, the sensing resistor is indicated by a dotted line for convenience of description. Throughout the present specification, a symbol ‘{ }’ represents a binary logic state.

An output current IO of 1 A is converted into a voltage source VIO of 1V and a second dependent current source IVIO of 1 mA, which is an output current source depending on the voltage source VIO. A diode current ID of 1 A is also converted into a diode voltage VID of 1V and a first dependent current source IVID of 1 mA, which is an output current source depending on the diode voltage VID. The output capacitor 140 of FIG. 1 is converted into the same kind of capacitor 240 of FIG. 2, and the equivalent series resistance 170 inside the output capacitor 140 of FIG. 1 is also converted into the same kind of resistance 270 of FIG. 2.

The descriptions based on the specific numerical values may be summarized in Table 1. The contents of FIG. 1 are only examples for describing the technical idea of the present invention, and the scope of the present invention is not defined or limited by the contents or numeral values.

TABLE 1

| FIG. 1 | | FIG. 2 | | | |
|---|---|---|---|---|---|
| Element | Value | Element | Value | Relation | Description |
| VIN | 24 V | IVIN | 2.4 mA | IVIN = | Input |
| | | | | VIN/10K | voltage |
| VO | 60 V | IVO | 6.0 mA | IVO = VO/10K | Output |
| | | | | | voltage |
| VSW | {0, VO} | SW | {HI, LO} | SW = VSW | Switching |
| | | | | logic value | voltage |
| VG | {LO, HI} | VG | {LO, HI} | | Switching |
| | | | | | control |
| | | | | | signal |
| L | 47 μH | C | 4.7 nF | C = L/10K | Inductor |
| Rsense | 0.1 Ω | Rs1, | {270 KΩ, | Rsense = | External |
| | | Rs2 | 30 KΩ} | Rs2/(Rs1 + | current |
| | | | | Rs2) | sensing |
| | | | | | resistor |
| IL | 1 A | VIL | 1 V | VIL = IL × 1 | Inductor |
| | | | | | current |
| IO | 1 A | VIO | 1 V | VIO = IO × 1 | Output load |
| | | | | | current |
| — | — | IVIO | 1 mA | IVIO = VIO × | Output load |
| | | | | 1K | current |
| ID | 1 A | VID | 1 V | VID = ID × 1 | Diode |
| | | | | | current |
| — | — | IVID | 1 mA | IVID = VID/ | Diode |
| | | | | 1K | current |
| CO | 47 μF | CCO | 47 nF | CCO = CO/1K | Output |
| | | | | | capacitor |
| ESR | 100 mΩ | RESR | 100 Ω | RESR = ESR × | Resistance |
| | | | | 1K | of output |
| | | | | | capacitor |

Referring to FIG. 1, the conversion process will be described in more detail. The technical accomplishment of the present inventors will be clarified by the descriptions.

In the related art, when the input voltage VIN is 24V and a supplied current is 1 A, input power becomes a large value of 24 W. The current value of about 1 A was sufficiently accepted by the inductor in the related art. In the embodiment of the present invention, however, the inductor current of the related art is converted into 2.4 mA. Although the input voltage is 10V, the input power is only 24 mW corresponding to 1/1,000 of the input power in the related art.

When there are three DC-DC converters to be tested, input power to be supplied in the related art as illustrated in FIG. 1 becomes a large value of 72 W (24 W×3). In this case, many problems occur as described above. For example, the supply ability of the testing device having an input power of 72 W may reach the limit thereof, and a large burden may be applied to the testing device. Furthermore, the precision of the testing device may decrease, and element heat caused by high power and a parasitic effect caused by various parasitic components may increase to reduce the reliability of the test.

As shown in Table 1, however, the inductor having a value of 47 μH in the related art is scaled down ten thousand times and converted to the capacitor 210 in the present invention. As a result, the value becomes a small value of 4.7 nF. Furthermore, a current inputted to or outputted from the capacitor 210 also decreases. Therefore, the above-described problem of the related art is minimized.

Furthermore, as shown in FIG. 1, the output capacitor 140 having a value of 47 μF in the related art is also scaled down thousand times and converted to the capacitor 240 having a value of 47 nF in the embodiment of the present invention. Since a current inputted to or outputted from the capacitor 240 also decreases, the burden of the testing device is reduced to improve the accuracy and precision of the test.

Meanwhile, as shown in FIG. 1, the equivalent series resistance must be scaled up as much as the capacitance is scaled down, in order to obtain the same frequency characteristic. In this case, an additional advantage may be acquired. The resistance has higher precision when a resistance of 100Ω is formed than when a resistance of 100 mΩ is formed. The reason is that an error of resistance has an absolute value. Furthermore, since the resistance of 100 mΩ in the related art is internal resistance, the resistance cannot be managed by a designer. However, since the resistance of 100Ω in the present invention may be set to an external resistance by a designer, it is easier to define and manage frequency characteristics. Therefore, the capacitors and the resistors according to the present invention are scaled up or scaled down in a desirable direction to solve the problem of the related art.

From two viewpoints, attention needs to be paid to the conversion of the two capacitors 210 and 240. First, the scaling units thereof are not fixed, but differently selected as 1/10,000 and 1/1,000, respectively. Second, not only the inductor 110 is converted into the capacitor 210, but also the capacitor 140 is converted into the capacitor 240. From this aspect, it can be seen that when one element is converted into another element, the types of the converted elements as well as the scaling units are thoroughly examined and researched.

Such efforts of the present inventors are revealed by the following example. As shown in FIG. 1, the output load current IO of 1 A is not converted into another element, but converted into two elements, that is, the voltage source VIO of 1V and the second dependent current source IVIO of 1 mA. Considering the above-described problems for the ability and precision of the testing device, the two elements, that is, the voltage source VIO of 1V and the second dependent current source IVIO of 1 mA are more favorable than the large current of 1 A.

The voltage source to generate a voltage of 1V in the present invention may be simply implemented with a MOS transistor. Furthermore, the dependent current source of 1 mA may also be easily obtained when a gate voltage is properly applied to a saturated MOS transistor.

As shown in Table 1, the diode current ID of 1 A is converted into two elements according to the above-described principle. That is, the diode current ID of 1 A is converted into a diode voltage VID of 1V and a first dependent current source IVID of 1 mA. From this aspect, it can be seen that the current source is not converted into only the voltage source. For reference, the dependent current source is represented by a diamond-shaped symbol in FIG. 2, which indicates that the dependent current source is controlled by the voltage.

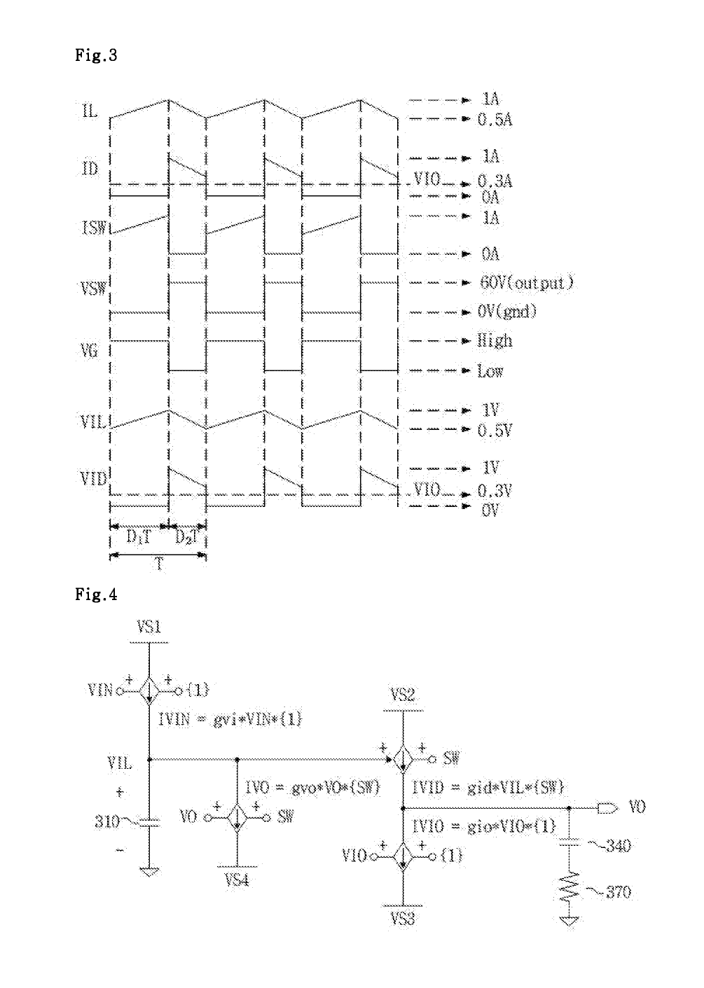

FIG. 3 is a timing diagram for explaining the circuit operations of FIGS. 1 and 2, in order to compare the present invention and the related art. FIG. 1 illustrates a circuit in which the input voltage VIN is set to 24V, the output voltage VO is set to 60V, and the current flowing in the inductor 210 ranges from 0.5 A to 1 A.

When the switching transistor 120 is turned on during a period D₁T, the switch node voltage VSW is grounded. Then, the current IL applied across the inductor 110 increases to 1 A, and the current ISW of the switching transistor 120 also increases. At this time, since the diode 130 is turned off, the current ID applied across the diode 130 does not flow. When the switching transistor 120 is turned off during a period D₂T, the switch current ISW does not flow, and the inductor current IL decreases to 0.5 A. At this time, the diode 130 is turned on, and the current ID flows but has a decreasing tendency.

When the switch 120 of FIG. 1 is turned on, that is, when the switching control signal VG is high, first switches 221A, 232A, and 231A are turned on and second switches 221B, 234B, and 233B are turned off in FIG. 2 according to the present invention. Then, the switch node voltage VISW is equalized to the input node voltage VIL, and the diode voltage VID becomes zero. On the other hand, when the switching transistor 120 of FIG. 1 is turned off, that is, when the switching control signal VG is low, the first switches 221A, 232A, and 231A are turned off and the second switches 221B, 234B, and 233B are turned on in FIG. 2 according to the present invention. Then, the switch node voltage VISW becomes zero, and the diode voltage VID is equalized to the input node voltage VIL.

FIG. 4 is a circuit diagram obtained by generalizing the embodiment of the present invention illustrated in FIG. 2. Like reference numerals represents the same components. All of the switches illustrated in FIG. 2 are omitted and indicated by symbols ‘SW’ and ‘{ }’ representing a switching state. For example, the input current source IVIN is connected to the input voltage VIN in FIG. 4, which indicates that the current value is dependent on the input voltage VIN. A symbol ‘{1}’ which is added to the input current source IVIN represents an on state in which the current of the input current source IVIN may flow. The state of the input current source IVIN may be logically expressed as follows: IVIN=gVI*VIN*{1}. Here, gVI represents a scaling factor for scaling a physical unit (for example: voltage-current conversion) and a magnitude, and the unit of gVI is trans-conductance. Furthermore, a symbol ‘*’ represents an AND operation.

In FIG. 4, the first dependent current source IVID serving as a dependent diode current source is also connected to the input node voltage VIL applied across the capacitor 310, which indicates that the current value of the first dependent current source IVID is dependent on the input node voltage VIL. A symbol ‘{SW}’ which is added to the first dependent current source IVID represents an on/off state in which the current of the first dependent current source IVID may flow or may not flow, depending on a switching state. The state of the first dependent current source IVID may be logically expressed as follows: IVID=gVID*VIL*{SW}. Here, gVID represents a scaling factor for scaling a physical unit (for example: voltage-current conversion) and a magnitude, and the unit of gVID is trans-conductance.

The output current source IVO illustrated in FIG. 4 is also dependent on the output voltage VO, and a symbol ‘{SW}’ which is added to the output current source IVO represents an on/off state in which the current of the first dependent current source IVID may flow or may not flow, depending on the switching state. The state of the output current source IVO may be logically expressed as follows: IVO=gVO*VO*{SW}. Here, gVO represents a scaling factor for scaling a physical unit (for example: voltage-current conversion) and a magnitude, and the unit of gVID is trans-conductance.

The second dependent current source IVIO illustrated in FIG. 4 is also dependent on the voltage of the voltage source VIO, and a symbol ‘{SW}’ which is added to the second dependent current source IVIO represents an on/off state in which the current may flow or may not flow depending on a switching state. The state of the second dependent current source IVIO may be logically expressed as follows: IVIO=gVIO*VIO*{1}. Here, gVIO represents a scaling factor for scaling a physical unit (for example: voltage-current conversion) and a magnitude, and the unit of gVID is trans-conductance.

The other passive elements, that is, the output capacitor 340, the resistance 370 of the output capacitor 340, and the capacitor 310 converted from the inductor are configured in the same manner as illustrated in FIG. 2, and thus the detailed descriptions thereof are omitted herein.

In all of the following drawings to be described below, an expression attached beside each current source may be analyzed as described above. When the current source is represented, the left side of the current source is connected to a voltage for controlling the current source, and the right side of the current source is connected to a switch for controlling the on/off state of the current source.

In FIG. 4, four current sources are first to fourth power supply voltages Vs1 to Vs4, respectively, and the power supply voltages may be determined as proper values by designers of the circuit. For example, the input current source IVIN and the first dependent current source IVID in FIG. 4 are connected to a voltage higher than a ground voltage, and the output current source IVO and the second dependent source IVIO are connected to the ground voltage.

So far, the technical ideas of the present invention, which has been described in the embodiment of the boost DC-DC converter, may be applied in the same manner to embodiments of a buck DC-DC converter and a boost-buck DC-DC converter.

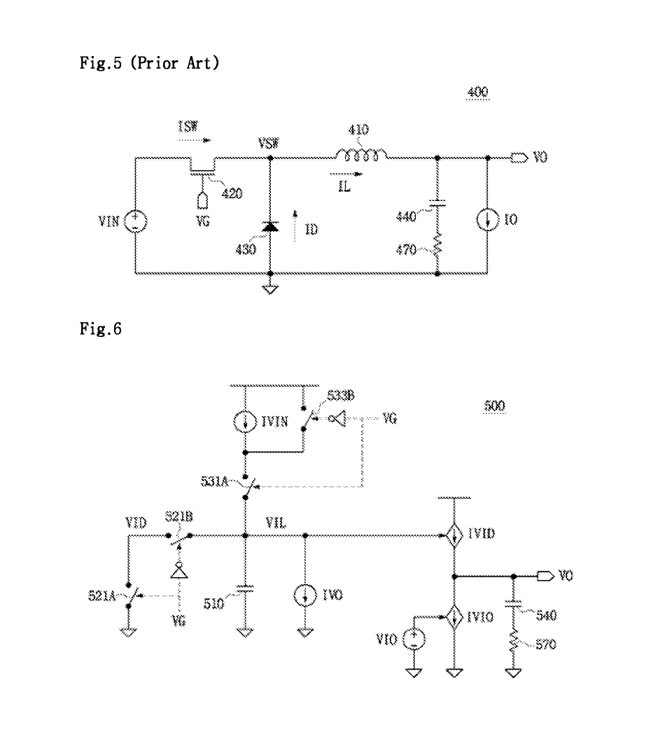

FIG. 5 illustrates a typical buck DC-DC converter. FIG. 6 illustrates a testing circuit for a buck DC-DC converter according to an embodiment of the present invention. In FIG. 6, components correspond one-to-one or one-to-two to components of the typical buck DC-DC converter. Depending on cases, the components may correspond one-to-three or more to the components of the typical buck DC-DC converter. When the embodiment of FIG. 6 is described, ‘present embodiment’ or ‘present invention’ represents the embodiment of the present invention illustrated in FIG. 6, and ‘related art’ represents the typical circuit illustrated in FIG. 5. However, ‘related art’ does not include all related arts published or proposed in the art.

The input current source IVIN in the present invention is converted in correspondence to the input voltage VIN in the related art. When the input voltage VIN is 24V, 24V is divided by 10KΩ and scaled down ten thousand times to the input current source IVIN of 2.4 mA. Since the voltage is converted into the current, the voltage is scaled down while the physical unit thereof is changed, but the voltage value thereof is not changed.

In this way, the output voltage VO in the related art is maintained as the output voltage VO in the present embodiment. The switch 420 (of FIG. 5) switched by the switching control signal VG in the related art is converted into first switches 521A and 531A and second switches 521B and 533B in the present embodiment. However, the states of the switches turned on/off by the switching control signal VG are different from each other.

The inductor 410 in the related art is converted into a capacitor 510 in the present embodiment. The inductor current IL is converted into an input node voltage VIL. However, the output current IO is converted into a voltage source VIO and a second dependent current source IVIO serving as a dependent output current source, and the diode current ID is converted into a diode voltage VID. Furthermore, the output capacitor 440 of FIG. 5 is converted into the same kind of capacitor 540 of FIG. 6, and the equivalent series resistance 470 inside the output capacitor 440 of FIG. 5 is converted into the same kind of resistance 570 of FIG. 6.

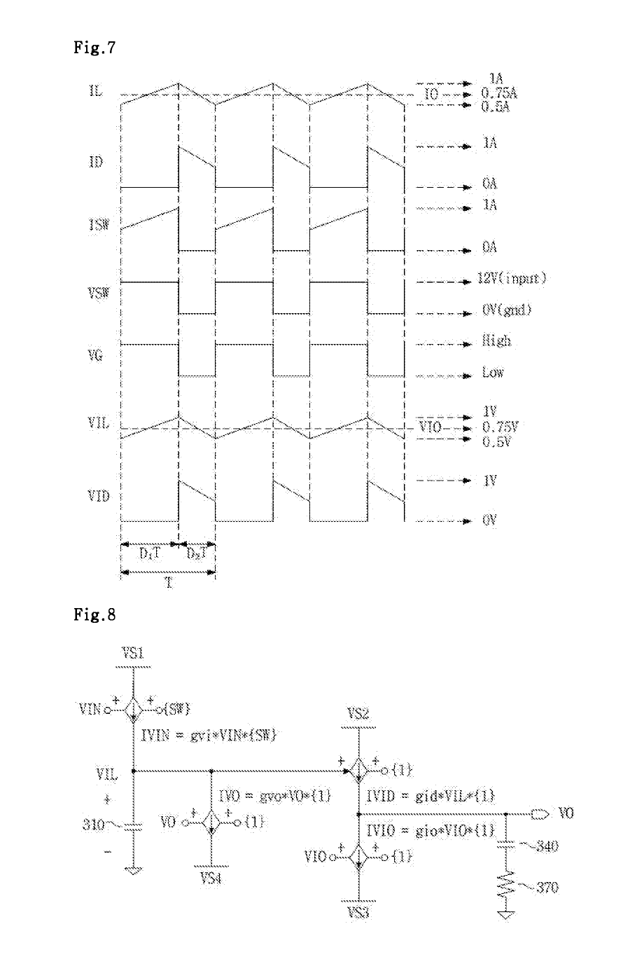

FIG. 7 is a timing diagram for explaining the circuit operations of FIGS. 5 and 6, in order to compare the present embodiment and the related art. In the circuit of FIG. 5, suppose that the input voltage VIN is 12V. Since the first embodiment of the present invention is the boost DC-DC converter, the output voltage VO is larger than the input voltage. However, the present embodiment is the buck DC-DC converter. Therefore, suppose that the output voltage VO is 12V lower than the input voltage VIN. Furthermore, suppose that the current IL of the inductor 410 ranges from 0.5 A to 1 A.

When the switching transistor 420 is turned on during a period D₁T, the node voltage VSW becomes 12V, the current ISW of the switching transistor 420 increases toward 1 A, and the inductor current IL also increases toward 1 A. At this time, since the diode 430 is turned off, the current ID applied across the diode does not flow.

When the switching transistor 420 is turned off during a period D₂T, the switch current ISW does not flow, but the inductor current IL decreases toward 0.5 A. At this time, the diode 430 is turned on, and the current ID flows but has a tendency of decreasing from 1 A. While such an operation is repeated at each period, the output current IO becomes 0.75 A corresponding to an average between the minimum value of 0.5 A and the maximum value of 1 A in the inductor current IL.

When the switching transistor 420 of FIG. 5 is turned on during the period D₁T, that is, when the switching control signal VG is high, the first switches 521A and 531A are turned on and the second switches 521B and 533B are turned off in the circuit of FIG. 6 according to the present embodiment. Then, the input node voltage VIL increases from 0.5V to 1V, and the node voltage VID is maintained at 0.

On the other hand, when the switch 420 is turned off during the D₂T, that is, when the switching control signal VG is low, the first switches 521A and 531A are turned off and the second switches 521B and 533B are turned on in the circuit of FIG. 6 according to the present embodiment. Then, the input node voltage VIL decreases from 1V to 0.5V, and the diode voltage VID instantly reaches 1V and simultaneously decreases toward zero.

The circuit of FIG. 6 is also only one embodiment for describing the technical idea of the buck DC-DC booster according to the embodiment of the present invention. A circuit configured by generalizing the technical idea of the buck DC-DC booster according to the embodiment of the present invention will be continuously described with reference to FIG. 8.

In FIG. 8, the input current source IVIN and the first dependent current source IVID are connected to the first and second power supply voltages Vs1 and Vs2, respectively, and the output current source IVO and the second dependent source IVIO are connected to the fourth and third power supply voltages Vs4 and Vs3, respectively, in the same manner as illustrated in FIG. 4. The other passive elements, that is, the output capacitor 340, the resistance 370 of the output capacitor, and the capacitor 310 converted from the inductor are configured in the same manner, and thus the detailed descriptions thereof are omitted herein.

However, the switching states of the respective current sources are different from each other. Since the switching state of the input current source IVIN is variable, the switching state is substituted with ‘{SW}’ in the logic expression of the input current source IVIN. Since the first dependent current source IVID, the output current source IVO, and the second dependent current source IVIO have a switching state in which they are always turned on, the switching state is fixed and represented as ‘{1}’ in each logic expression.

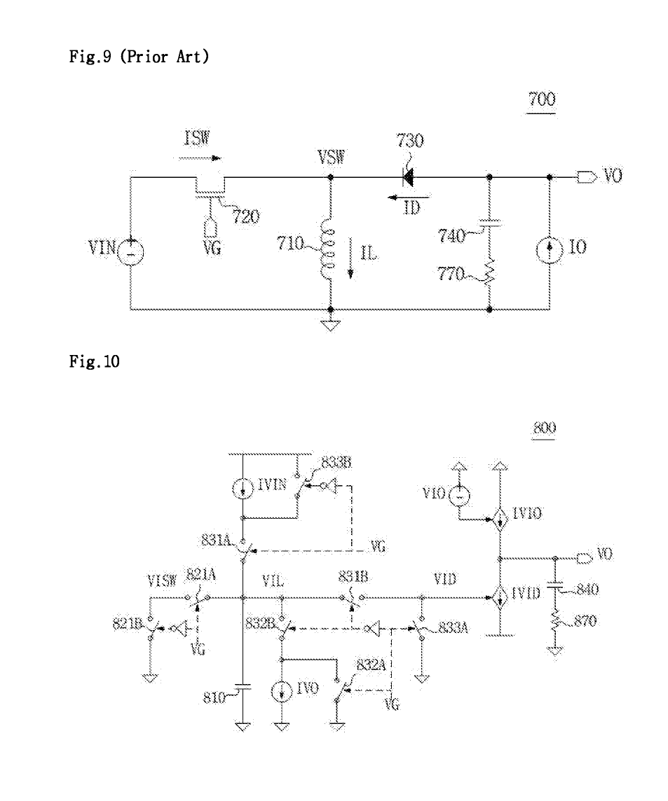

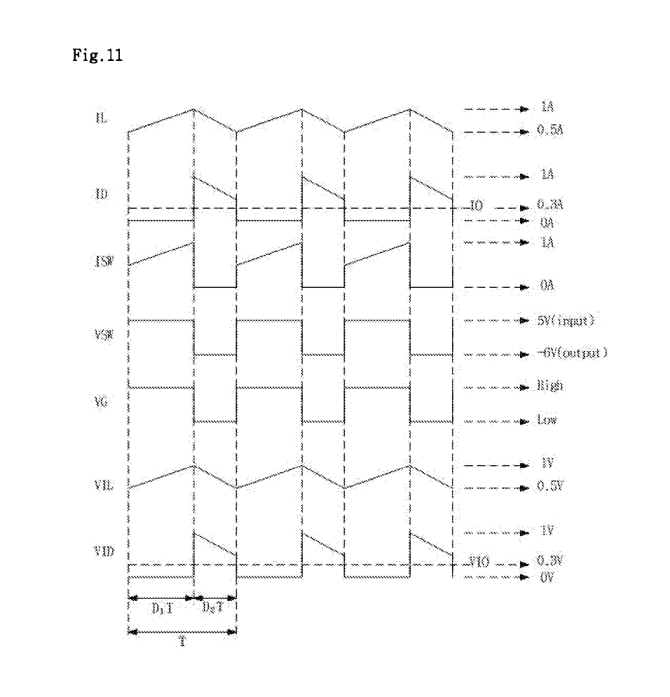

FIG. 9 illustrates a typical boost-buck DC-DC converter. FIG. 10 illustrates a testing circuit for a boost-buck DC-DC converter according to a corresponding embodiment of the present invention. In FIG. 10, components correspond one-to-one or one-to-two to components of the typical boost-buck DC-DC converter of FIG. 9. Depending on cases, the components correspond one-to-three or more to the components of the typical boost-buck DC-DC converter of FIG. 9. In the following descriptions, ‘present embodiment’ or ‘present invention’ represents the embodiment of the present invention illustrated in FIG. 10, and ‘related art’ represents the typical circuit illustrated in FIG. 9. However, ‘related art’ does not include all related arts published or proposed in the art.

The input current source IVIN in the present invention corresponds to the input voltage VIN in the related art. When the input voltage VIN is 24V, 24V is divided by 10KΩ and scaled down ten thousand times to the input current source of 2.4 mA. This aspect is the same as the two above-described embodiments, and the detailed descriptions thereof are omitted herein.

In this way, the output voltage VO in the related art is converted into the output voltage VO in the present embodiment, like the two above-described embodiments. A switch 720 switched by the switching control signal VG in the related art is converted into first switches 821A, 831A, 832A, and 833A and second switches 821B, 831B, 832B, and 833B in the present embodiment. However, the states of the switches turned on/off by the switching control signal VG are different from each other. An inductor 710 in the related art is converted into a capacitor 810 in the present embodiment. An inductor current IL is converted into a node voltage VIL.

However, an output current IO is converted into a voltage source VIO and a second dependent current source IVIO serving as an output dependent current source, and a diode current ID is converted into a diode voltage VID and a first dependent current source IVID serving as an output dependent current source.

However, the second dependent current source IVIO is connected to a ground voltage, and the first dependent current source IVID is connected to a power supply voltage. Due to the connection different from that of the embodiment of FIG. 2 or 6, the direction of the current is changed.

A current ISW flowing in the switch 720 is converted into a switch node voltage VISW. Furthermore, an output capacitor 740 of FIG. 9 is converted into the same kind of capacitor 840 of FIG. 10, and an equivalent series resistance 770 inside the output capacitor 740 of FIG. 9 is converted into the same kind of resistance 870 of FIG. 10.

FIG. 11 is a timing diagram for explaining the circuit operations of FIGS. 9 and 10, in order to compare the present embodiment and the related art. Like the two above-described embodiments, suppose that the input voltage VIN is 5V and the output voltage VO is −6 in the circuit of FIG. 9. The present embodiment is a boost-buck DC-DC converter. Therefore, suppose that the node voltage VSW ranges from the input voltage VIN to the output voltage VO. Furthermore, suppose that the current IL of the inductor 710 ranges from 0.5 A to 1 A.

When the switching transistor 720 is turned on during a period D₁T, the node voltage VSW becomes 5V, the current ISW of the switching transistor 720 increases toward 1 A, and the inductor current IL also increases toward 1 A. At this time, since the diode 730 is turned off, the current ID applied across the diode does not flow.

When the switching transistor 720 is turned off during a period D₂T, the switch current ISW does not flow, and the inductor current IL decreases toward 0.5 A. At this time, the diode 730 is turned on, and the diode current ID flows but has a tendency of decreasing from 1 A. While such an operation is repeated at each period, the output current IO becomes 0.3 A corresponding to an average between the minimum value of OA and the maximum value of 1 A in the inductor current IL.

When the switching transistor 720 of FIG. 9 is turned on during the period D₁T, that is, the switching control signal VG is high, the first switches 821A, 831A, 832A, and 833A are turned off and the second switches 821B, 831B, 832B, and 833B are turned on in the circuit of FIG. 10 according to the present embodiment. Then, the node voltage VIL increases from 0.5V to 1V, and the diode voltage VID is maintained at 0V. On the other hand, when the switch 720 is turned off during the period D₂T, that is, when the switching control signal VG is low, the first switches 821A, 831A, 832A, and 833A are turned on and the second switches 821B, 831B, 832B, and 833B are turned off in the circuit of FIG. 10 according to the present embodiment. Then, the input node voltage VIL has a tendency of decreasing from 1V to 0.5V, and the diode voltage VID instantly reaches 1V and simultaneously decreases toward 0V. At this time, the voltage source VIO maintains a stable value of 0.3V.

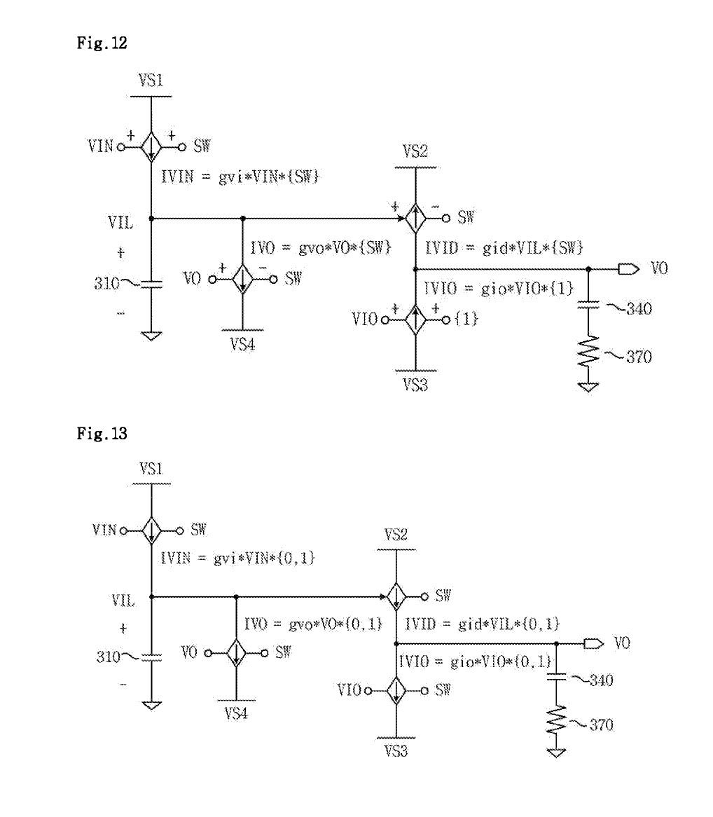

In FIG. 12, the input current source IVIN and the first dependent current source IVID are connected to the first and second power supply voltages Vs1 and Vs2, respectively, and the output current source IVO and the second dependent current source IVIO are connected to the fourth and third power supply voltages Vs4 and Vs3, respectively, in the same manner as illustrated in FIG. 4. The other passive elements, that is, the output capacitor 340, the resistance 370 of the output capacitor, and the capacitor 310 converted from the inductor are configured in the same manner, and thus the detailed descriptions thereof are omitted herein. However, the switching states of the respective current sources are different from each other. Since the switching state of the input current source IVIN is variable, the switching state is substituted with ‘{SW}’ in the logic expression of the input current source IVIN. The first dependent current source IVID, the output current source IVO, and the second dependent current source IVIO are configured in the same manner as illustrated in FIG. 4.

However, the current flow directions of the first and second dependent current sources IVID and IVIO are changed to a direction from the third power supply voltage Vs3 to the second power supply voltage Vs2. This reflects that the current flow directions of the first and second dependent current sources IVID and IVIO were changed in FIG. 10.

So far, the three embodiments of the present invention have been described with reference to the specific circuits of the present invention and the generalized circuits. However, the technical idea of the present invention is not limited only to the circuit connection state in which the components are converted, but lies in the conversion of the circuit. In the three above-described embodiments, the ratio of input voltage to output voltage has been used to describe the conversions of the boost, buck, and boost-buck DC-DC converters. However, the technical idea of the present invention may be applied to all types of switching DC-DC converters depending on the classification method. The application will be described below in more detail.

Hereinafter, several outstanding features of the technical idea of the present invention will be described in more detail.

In FIGS. 1, 5, and 9 illustrating typical DC-DC converters, the input voltage VIN is converted into the input current IVIN in FIG. 2. Depending on cases, the switches 531A and 533B of FIG. 6 or the switches 831A and 833B of FIG. 10 may be added.

The inductors 210, 410, and 710 serving an energy storage element in the typical DC-DC converters are converted into capacitors 310, 510, and 810, respectively, corresponding to a different type of energy storage element in the present invention. That is, the current energy storage element is scaled down and converted into the voltage energy storage element.

Among the core elements forming the typical DC-DC converters, the switches 220, 420, and 720 are converted into the first switches and the second switches, and the first switches and the second switches operate at different phases, respectively.

The diodes 230, 430, and 730 in the typical DC-DC converters are converted into a part of the switches of the two groups in the present invention. This is because the switching operations of the typical DC-DC converters have an effect on the on and off operations of the diodes 230, 430, and 730. At this time, the diode current of the typical DC-DC converter is converted into the node voltage VID in the present embodiment.

Depending on cases, the first dependent current source IVID serving as a dependent current source may be added as illustrated in FIGS. 2 and 10.

In the typical DC-DC converter, the output capacitors 240, 440, and 740 serving as an energy storage element at the output side may be converted into the capacitors 340, 540, and 840 serving as the same kind of energy storage element. In this case, the output capacitors may be scaled down.

In the typical DC-DC converter, the output current IO to be supplied is converted into the voltage source IVO which may be scaled down and the second dependent current source IVIO which is a current source dependent on the voltage source IVO.

As described above, the switching actions by the switching control signal VG in the respective embodiments of the present invention are a little bit different from each other depending on the types of the typical DC-DC converters. This indicates that the conversion from the typical DC-DC converter to the embodiments of the present invention was examined very carefully and thoroughly. In this way, the embodiments of the inductor-less testing circuit for a DC-DC converter are completed.

As illustrated in FIG. 2, the input current source IVIN may be directly connected to the node voltage VIL, and may be connected through the switch as illustrated in FIGS. 6 and 10.

Therefore, the supposition that the expression of ‘electrically connected’ in the present invention is not limited only to the direct connection but includes a connection through an intermediate medium may be determined to be reasonable. Furthermore, expressions similar to ‘electrically connected’ may be analyzed in the same manner.

FIGS. 2, 6, and 10 illustrate the specific embodiments in which the technical idea of the present invention has been described in more detail, and FIGS. 4, 8, and 12 illustrate the circuits obtained by generalizing the specific embodiments.

Meanwhile, the entire technical idea of the present invention may be included in one circuit diagram, and will be described with reference to FIG. 13.

Referring to FIG. 13, the positions of the current sources and the passive elements are set as illustrated in FIGS. 4, 8, and 12. Since the passive elements 310, 340, and 370 have the same role, like reference numerals are attached thereto. The input current source IVIN is connected to the input voltage VIN, which indicates that the current value of the input current source IVIN is dependent on the input voltage VIN.

A symbol ‘SW’ added to the right side of the input current source IVIN represents a signal to control the switching operation of the input current source IVIN. Depending on the state of the symbol ‘SW’, the input current source IVIN may be turned on at all times as illustrated in FIG. 4, or may be switched between the on and off states as illustrated in FIG. 8. The state of the input current source IVIN may be expressed as follows: IVIN=gVI*VIN*{0,1}. Here, {0,1} includes {0} indicating that the input current source IVIN is fixed to the off state, {1} indicating that the input current source IVIN is fixed to the on state, and {SW} indicating that the input current source IVIN is switched between the on and off states. This aspect is applied in the same manner to other current sources. Three different current sources, that is, the first dependent current source IVID, the output current source IVO, and the second dependent current source IVIO are connected to a node voltage VIL, an output voltage VO, and a voltage source VIO. A symbol ‘SW’ added to the right side of each current source means that the switching operation of the current source is controlled by the signal SW.

So far, after the specific embodiments of FIGS. 2, 6, and 10 and the generalized embodiments of FIGS. 4, 8, and 12 were described, the technical idea of the present invention has been described with reference to the circuit of FIG. 13 which collectively includes the technical idea of the present invention.

According to the embodiments of the present invention, the testing circuit for a DC-DC converter may be implemented without an inductor, and may test the functionality of the DC-DC converter without passing a large current.

Although a preferred embodiment of the present invention has been described for illustrative purposes, those skilled in the art will appreciate that various modifications, additions and substitutions are possible, without departing from the scope and the spirit of the invention as disclosed in the accompanying claims.

What is claimed is:

1. A testing circuit for a DC-DC converter, comprising:
an input current source;
a first energy storage element having one terminal electrically connected to the input current source and the other terminal connected to a ground voltage;
a plurality of first switches and second switches controlled by a switching control signal;
a voltage source interconnected to a current value flowing in an output terminal;
a first dependent current source having one terminal connected to the output terminal and controlled by a diode voltage;
a second dependent current source having one terminal connected to the output terminal and the one terminal of the first dependent current source and controlled by a voltage of the voltage source;
an output current source having one terminal connected to one or more of the first switches and the other terminal connected to the ground voltage; and
a second energy storage element connected to the output terminal.

2. The testing circuit of claim 1, wherein the first and second energy storage elements comprise a capacitive load.

3. The testing circuit of claim 1, wherein the testing circuit for the DC-DC converter comprises one of boost, buck, and boost-buck circuits.

4. The testing circuit of claim 1, wherein the first and second dependent current sources are connected in series between a power supply voltage and the ground voltage.

5. The testing circuit of claim 1, wherein the first switches and the second switches operate in the opposite phase.

6. The testing circuit of claim 5, wherein the first switches and the second switches comprise transistors.

7. The testing circuit of claim 1, wherein the switching control signal comprises a signal which is repeated with a predetermined period.

8. The testing circuit of claim 1, wherein the output current source is electrically connected to the input current source, and has a current value interconnected to the voltage of the output terminal.

9. A testing circuit for a DC-DC converter which has an input terminal to receive an input current source and an output terminal to output an output voltage, the testing circuit comprising:
a plurality of first switches electrically connected to the input terminal and controlled by a switching control signal;
a plurality of second switches electrically connected to the input terminal, controlled by the switching control signal, and operating in the opposite phase of the first switches;
a first capacitor electrically connected to the input terminal;
an output current source electrically connected to the input terminal;
a second capacitor electrically connected to the output terminal;
a first dependent current source having one terminal electrically connected to the output terminal;
a second dependent current source electrically having one terminal electrically connected to the output terminal; and
a voltage source interconnected to a current value flowing in the output terminal.

10. The testing circuit of claim 9, wherein the current value of the output current source is interconnected to the output voltage.

11. The testing circuit of claim 9, wherein any one of the first and second dependent current sources has a current value interconnected to the output voltage.

12. The testing circuit of claim 9, wherein any one of the first and second dependent current sources has a current value dependent on the voltage value of the voltage source.

13. The testing circuit of claim 9, wherein the other terminal of the first dependent current source, which is not electrically connected to the output terminal, is connected to a power supply voltage or ground voltage.

14. The testing circuit of claim 9, wherein the other terminal of the second dependent current source, which is not electrically connected to the output terminal, is connected to a power supply voltage or ground voltage.

15. The testing circuit of claim 9, wherein the first and second dependent current sources are connected in series between a power supply voltage and a ground voltage.

16. The testing circuit of claim 9, wherein the input current source and the first capacitor are connected in series between a power supply voltage and a ground voltage.

17. A testing circuit for a DC-DC converter, comprising:
a first current source having one terminal connected to a first power supply voltage, dependent on an input voltage, and controlled by a first switching signal;
a first capacitor connected between the other terminal of the first current source and a ground voltage;
a second current source having one terminal connected to a second power supply voltage, dependent on the voltage of the other terminal of the first current source, and controlled by a second switching signal;
a fourth current source connected between the other terminal of the first current source and a fourth power supply voltage, dependent on an output voltage, and controlled by a fourth switching signal; and
a third current source connected between the other terminal of the second current source and a third power supply voltage, dependent on a voltage converted from an output load current, and controlled by a third switching signal.

18. The testing circuit of claim 17, wherein a node of the output voltage is connected to an output capacitor and an output resistor.

19. The testing circuit of claim 17, wherein the first current source has a current value determined by the input voltage, a switching state of the first switching signal, and a first scale factor,
the second current source has a current value determined by a voltage of the other terminal of the first current source, a switching state of the second switching signal, and a second scale factor,
the fourth current source has a current value determined by the output voltage, a switching state of the fourth switching signal, and a fourth scale factor, and
the third current source has a current value determined by a voltage converted from the output load current, a switching state of the third switching signal, and a third scale factor.

20. The testing circuit of claim 19, wherein the first to fourth scale factors have a physical unit of conductance.

21. The testing circuit of claim 17, wherein the second power supply voltage is lower than the third power supply voltage.
